(19) United States
(12) Patent Application Publication
(10) Pub. No.: US 2010/0258437 A1
(43) Pub. Date: Oct. 14, 2010

(54) APPARATUS FOR REACTIVE SPUTTERING DEPOSITION

(76) Inventors: Woo Seok Cheong, Daejeon (KR); Chi Sun Hwang, Daejeon (KR); Min Ki Ryu, Seoul (KR)

Correspondence Address: RABIN & Berdo, PC, 1101 14TH STREET, NW, SUITE 500, WASHINGTON, DC, 20005, US

(21) Appl. No.: 12/741,667

(22) PCT Filed: Sep. 2, 2008
(86) PCT No.: PCT/KR2008/005125

§ 371 Date: May 6, 2010

(30) Foreign Application Priority Data
Nov. 9, 2007 (KR) 10-2007-0114365

(51) Int. Cl. C23C 14/34

(52) U.S. Cl. 204/298.07; 204/298.02

(57) ABSTRACT

Provided is a reactive sputtering apparatus, and more particularly, a reactive sputtering apparatus capable of effectively ionizing a reactive gas using inductively coupled plasma (ICP). The reactive sputtering apparatus includes: a chamber having an inlet port for introducing a plasma gas thereinto and an outlet port for exhausting the gas used during reactive sputtering to the exterior; an ICP generator disposed on the chamber, ionizing a reactive gas, and injecting the ionized gas into the chamber; and at least one sputter gun located at a side surface of the chamber and supporting a target. Therefore, the reactive sputtering apparatus can improve an ionization rate of a reactive gas using inductively coupled plasma to reduce a process temperature and improve uniformity and step coverage of thin film deposition at low cost.

### TECHNICAL FIELD

The present invention relates to an apparatus for reactive sputtering deposition, and more particularly, to an apparatus for reactive sputtering deposition capable of effectively ionizing a reactive gas using inductively coupled plasma (ICP).

This work was supported by the IT R&D program of MIC/IITA. [2006-S-079-02, Smart window with transparent electronic devices].

### BACKGROUND ART

Methods of depositing a metal oxide thin film include a chemical vapor deposition (CVD) method, a sputtering method, a molecular beam epitaxy (MBE) method, and an electron beam (E-beam) method, among others. Among these methods, the sputtering method is a method of forming plasma using an inert gas such as argon gas, and colliding cations of the inert gas with a target material to deposit the separated target material on a substrate.

A conventional sputtering apparatus has a relatively simple structure including a DC power supply, an RF plasma source, a magnetron gun, and so on. The deposition performed using the conventional sputtering apparatus has advantages of enabling deposition at a normal temperature and over a large area. However, straightness and chemical characteristics of deposition particles lower step coverage and deteriorate density and absorption characteristics of the thin film.

In particular, in the case of a reactive sputtering method using a reactive gas to induce deposition of a target material, in order to solve the above problems, methods of increasing an ionization rate of a reactive gas using a microwave, a filament, an ion gun, and so on, to improve quality of a thin film have been proposed. However, use of the microwave increases deposition cost of the thin film, and use of the filament causes difficulties in maintenance and management and generates contaminations. In addition, use of the ion gun is inappropriate to the deposition over the large area.

### DISCLOSURE OF INVENTION

### Technical Problem

The present invention, therefore, solves the aforementioned problems associated with conventional devices by providing a reactive sputtering apparatus capable of effectively increasing an ionization rate of a reactive gas during a reactive sputtering process.

### Technical Solution

In an exemplary embodiment of the present invention, a reactive sputtering apparatus includes: a chamber having an inlet port for introducing a plasma gas thereinto and an outlet port for exhausting the gas used during reactive sputtering deposition to the exterior; an ICP generator disposed above the chamber, ionizing a reactive gas, and injecting the ionized gas into the chamber; and at least one sputter gun located at a side surface of the chamber and supporting a target.

### Advantageous Effects

As can be seen from the foregoing, a reactive sputtering apparatus in accordance with the present invention can improve an ionization rate of a reactive gas using inductively coupled plasma to reduce a process temperature and improve uniformity and step coverage of thin film deposition at low cost.

In addition, a target fixed to a sputter gun can be vertically moved to uniformly use the entire target, thereby reducing material cost.

Further, the sputter gun is disposed perpendicular to a substrate to prevent damage to the substrate due to kinetic energy of particles.

### BRIEF DESCRIPTION OF THE DRAWINGS

The above and other features of the present invention will be described in reference to certain exemplary embodiments thereof with reference to the attached drawings in which:

FIG. 1 is a view showing the constitution of a reactive sputtering apparatus in accordance with an exemplary embodiment of the present invention;

FIG. 2 is a plan view of the reactive sputtering apparatus in accordance with an exemplary embodiment of the present invention; and

FIG. 3 is a front view of a sputter gun installed in the reactive sputtering apparatus in accordance with an exemplary embodiment of the present invention.

### MODE FOR THE INVENTION

The present invention will now be described more fully hereinafter with reference to the accompanying drawings, in which preferred embodiments of the invention are shown.

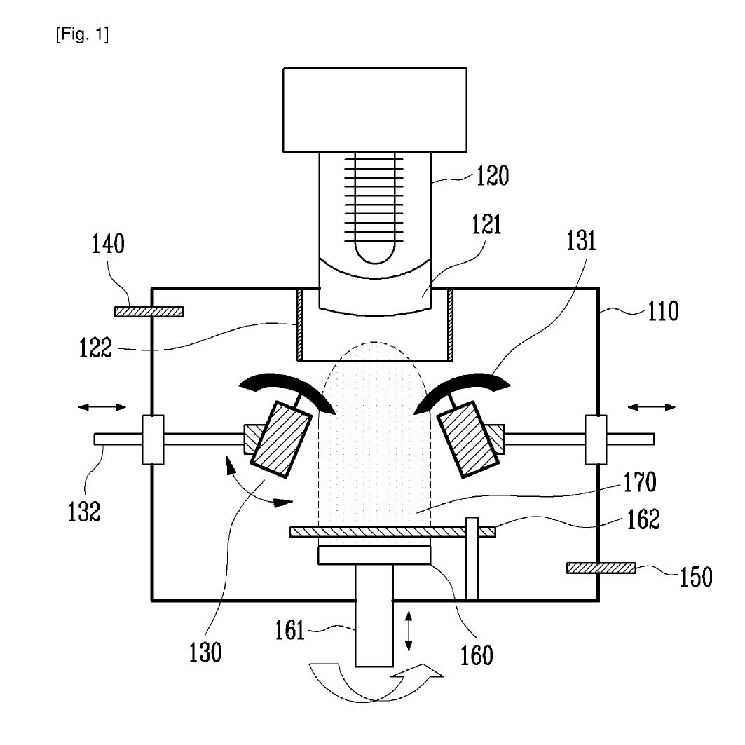

FIG. 1 is a view showing the constitution of a reactive sputtering apparatus in accordance with an exemplary embodiment of the present invention.

Referring to FIG. 1, the reactive sputtering apparatus 100 includes a chamber 110 in which a deposition process is performed, an inductively coupled plasma (ICP) generator 120 for ionizing a reactive gas, sputter guns 130 for supporting a target to be sputtered, and an inlet port 140 and an outlet port 150 for injecting the gas into the chamber 110 or exhausting the gas to the exterior.

The ICP generator 120, disposed above the chamber 110, is an apparatus for generating plasma using an induction coil in a frequency region generated from a high frequency generator. In a deposition process, the ICP generator 120 ionizes a reactive gas such as nitrogen, or oxygen, and injects the ionized gas into the chamber 110. In one exemplary embodiment, the ICP generator 120 can ionize the reactive gas using a frequency range of 13.56 MHz to 27.12 MHz. At this time, a vertical distance between the ICP generator 120 and a substrate 160 can be adjusted using a bellows 121 of the ICP generator 120.

In addition to the reactive gas introduced by the ICP generator 120, a plasma gas including the reactive gas in plasma and a sputtering gas can be introduced into the chamber 110 through the inlet port disposed above the chamber 110. Here, the sputtering gas includes an inert gas such as argon gas. In addition, the gas used during the deposition process can be discharged to the exterior of the chamber 110 through the outlet port 150.

A barrier 122 having a cylindrical shape is installed above the chamber 110, at which the ICP generator 120 is located, to block the ionized gas introduced from a side thereof. The barrier 122 can protect the ICP generator 120 and can concentrate the ionized gas between the sputter guns 130 in order to increase deposition efficiency. In one exemplary embodiment, in order to increase protection and concentration efficiency, the height of the barrier 122 may correspond to a half of a distance between the upper surface of the chamber 110 and the sputter gun 130, and the diameter of the barrier 122 may be 120% to 200% of the diameter of the ICP generator 120. In addition, the interior of the barrier 122 may be coated with a ceramic material such as alumina, and so on, in order to protect the interior from the ionized gas.

At least one sputter gun 130 for supporting a target is installed at the side surface of the chamber 110 in a direction perpendicular to the substrate 160, and can be angularly adjusted within a 45° range from a direction perpendicular to the substrate 160. As described above, the sputter gun 130 and the substrate 160 may be disposed in an off-axis manner to reduce damage to the substrate 160 due to the sputtered particles.

A gun shutter 131 may be attached to an upper part of the sputter gun 130 to protect the sputter gun 130 from the gas ionized by the ICP generator 120 and prevent contamination thereof. In one exemplary embodiment, the gun shutter 131 may be formed of stainless steel or may be coated with a ceramic material which is resistive to the ionized gas. In addition, a distance between the sputter guns 130 can be adjusted using sputter gun supporters 132 coupled to the sputter guns 130. The sputter gun supporters 132 can pass through sidewalls of the chamber 110 to be controlled from the exterior.

A plasma region 170 is formed between the reactive gas ionized by the ICP generator 120 and the sputter gun 130. The plasma region 170 may be varied depending on an angle of the sputter gun 130, a distance between the ICP generator 120 and the substrate 160, and deposition conditions.

The substrate 160 is disposed in a direction perpendicular to the sputter gun 130 and fixed to a substrate supporter 161 to oppose the ICP generator 120. Here, the substrate supporter 161 is disposed on bottom of the chamber. In order to optimize deposition uniformity and so on, the substrate supporter 161 can be rotated and vertically adjusted. A substrate shutter 162, capable of blocking the gas in the chamber 110 from the substrate 160 according to external control, is installed above the substrate 160 to protect the substrate 160 during preliminary sputtering and effectively adjust the thickness of a thin film deposited on the substrate 160.

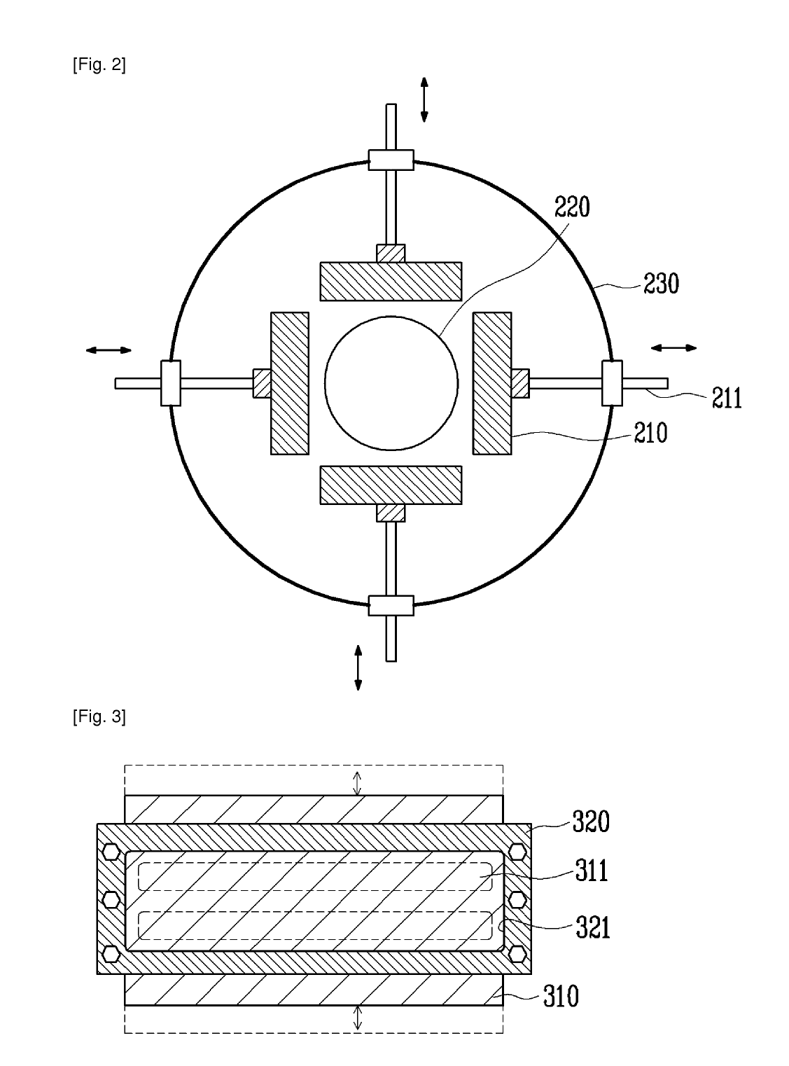

FIG. 2 is a plan view of the reactive sputtering apparatus in accordance with an exemplary embodiment of the present invention.

Referring to FIG. 2, when a plurality of sputter guns 210 are installed, in order to optimize deposition uniformity, the angle and distance between the sputter guns 210 may be adjusted based on some considerations such as the size of a substrate 220. In one exemplary embodiment, two to four sputter guns 210 may be installed at side surfaces of a chamber 230 at 90° to 180° intervals to deposit a thin film in good quality. Here, as described above, the distance between the sputter guns 210 may be adjusted using sputter gun supporters 211.

In addition, each of the sputter guns 210 may hold the same or different kinds of target materials depending on composition of the thin film. The length of the sputter gun 210 may be larger than the diameter of the substrate 220 by 10% to 50% in order to guarantee deposition uniformity.

FIG. 3 is a front view of a sputter gun installed in the reactive sputtering apparatus in accordance with an exemplary embodiment of the present invention.

Referring to FIG. 3, a sputter gun cover 320 having an opening 321 for exposing a target 310 to plasma is fixed to the front surface of the sputter gun using fasteners, and the target 310 is supported between the sputter gun and the sputter gun cover 320 by the sputter gun. In one exemplary embodiment, the sputter gun may be formed of a magnetron gun having a rectangular shape.

In general, the magnetron sputter gun has a disadvantage in that sputtering is performed on a portion of the target of the sputter gun. In order to solve the problem, the sputter gun vertically moves the target 310, a specific part 311 of which is used, using a motor, or the like, such that the remained part of the target is disposed at a rear surface of the opening 321 of the sputter gun cover 320. Therefore, the remained part of the target 310 is also used by the sputtering to increase the entire use efficiency of the target 310. In one exemplary embodiment, since the target 310 can be vertically moved and have a size larger than the sputter gun by 10% to 20%, it is possible to increase the amount of the target 310 that can be used during the sputtering process.

Although the present invention has been described with reference to certain exemplary embodiments thereof, it will be understood by those skilled in the art that a variety of modifications and variations may be made to the present invention without departing from the spirit or scope of the present invention defined in the appended claims, and their equivalents.

1. A reactive sputtering apparatus for performing reactive sputtering deposition on a substrate using a reactive gas, comprising:
a chamber having an inlet port for introducing a plasma gas thereinto and an outlet port for exhausting the gas used during the reactive sputtering deposition to the exterior;
an ICP generator disposed above the chamber, ionizing the reactive gas, and injecting the ionized gas into the chamber; and
at least one sputter gun located at a side surface of the chamber and supporting a target.

2. The reactive sputtering apparatus according to claim 1, further comprising a bellows disposed below the ICP generator and adjusting a vertical distance between the ICP generator and the substrate.

3. The reactive sputtering apparatus according to claim 1, wherein the ICP generator ionizes the reactive gas using a frequency of 13.56 MHz to 27.12 MHz.

4. The reactive sputtering apparatus according to claim 1, further comprising a barrier disposed below the ICP generator and blocking the plasma gas introduced through the inlet port from the ICP generator.

5. The reactive sputtering apparatus according to claim 4, wherein the barrier has a cylindrical shape and a diameter which is 120% to 200% of the diameter of the ICP generator.

6. The reactive sputtering apparatus according to claim 4, wherein the barrier is coated with a ceramic material including alumina.

7. The reactive sputtering apparatus according to claim 1, wherein an inclination of the at least one sputter gun is adjusted within a range of 0° to 45° with respect to a vertical direction of the substrate.

8. The reactive sputtering apparatus according to claim 1, further comprising a sputter gun supporter disposed at a side surface of the chamber, and having one side which supports the at least one sputter gun and the other side which is connected to the exterior through a sidewall of the chamber.

9. The reactive sputtering apparatus according to claim 8, wherein a distance between the at least one sputter gun is adjusted using the sputter gun supporter.

10. The reactive sputtering apparatus according to claim 1, further comprising a gun shutter fixed to an upper part of the at least one sputter gun and protecting the at least one sputter gun from the reactive gas ionized by the ICP generator.

11. The reactive sputtering apparatus according to claim 10, wherein the gun shutter is formed of stainless steel or coated with a ceramic material.

12. The reactive sputtering apparatus according to claim 1, wherein the at least one sputter gun supports different kinds of targets.

13. The reactive sputtering apparatus according to claim 1, wherein the at least one support gun has a length larger than the diameter of the substrate by 10% to 50%.

14. The reactive sputtering apparatus according to claim 1, further comprising a substrate supporter disposed on bottom of the chamber and fixing the substrate.

15. The reactive sputtering apparatus according to claim 14, wherein the substrate supporter is vertically movable or rotatable.

16. The reactive sputtering apparatus according to claim 1, further comprising a substrate shutter disposed above the substrate and blocking the plasma gas from the substrate.

17. The reactive sputtering apparatus according to claim 1, wherein the target is vertically movable in front of the at least one sputter gun.

18. The reactive sputtering apparatus according to claim 17, wherein the target is larger than the at least one sputter gun by 10% to 20%.
